(19) United States
(12) Patent Application Publication
(10) Pub. No.: US 2017/0322262 A1
(43) Pub. Date: Nov. 9, 2017

(54) SYSTEM AND METHOD FOR ESTIMATING STATE OF HEALTH OF CAPACITIVE DEVICE

(71) Applicant: The Paper Battery Company, Inc., Troy, NY (US)

(72) Inventor: Gene Lee ARMSTRONG, II, Richardson, TX (US)

(73) Assignee: The Paper Battery Company, Inc., Troy, NY (US)

(21) Appl. No.: 15/586,421

(22) Filed: May 4, 2017

Related U.S. Application Data
(60) Provisional application No. 62/331,625, filed on May 4, 2016.

(51) Int. Cl. G01R 31/36

(52) U.S. Cl. CPC G01R 31/3679; G01R 31/3651; G01R 31/3662

(57) ABSTRACT

State of health processes and systems are provided for analyzing a capacitor, such as a supercapacitor. The process includes, for instance: determining a measured capacitance of a capacitor; estimating an effective series resistance (ESR) of the capacitor; determining, using the measured capacitance and the effective series resistance, a linearized capacitance parameter (CAP) for the capacitor; and signaling should the CAP drop below, or the ESR rise above, a respective specified threshold for the capacitor. Using the CAP and the effective series resistance, an amount of energy remaining in the capacitor may be determined, upon which to base one or more actions.

### CROSS-REFERENCE TO RELATED APPLICATION

This application claims the benefit of U.S. provisional patent application Ser. No. 62/331,625, filed May 4, 2016, which is hereby incorporated herein by reference in its entirety.

### BACKGROUND

High reliability energy storage is desired in many aspects of data storage. Any instance where a loss of power will result in a loss of data would require a persistent energy source to, for instance, facilitate an orderly system shutdown. Fundamentally, data may be stored in a volatile media, such as cache SRAM or DRAM memory, for quick access and wear prevention until a system shutdown is required. This data can be vulnerable to power loss and therefore persistent power is desirable in order to preserve this information to slower media such as FLASH memory or disk-drive on power loss. This restriction is often found in, but not limited to, NVDIMM, RAID and SSD components within a computing platform. Traditionally, backup systems for such applications have utilized supercapacitors, tantalum capacitors or electrolytic capacitors (traditional devices) for energy storage. Due to the low volumetric energy density of traditional devices, the industry is constantly in search of further capacitive technologies, such as the asymmetric-supercapacitor or hybrid-supercapacitor. The system requirements for backup energy are typically specified in terms of Joules delivered at a specific power to perform and complete the task of data transference.

Within above-noted environments, the ability to monitor the status of capacitors during use remains an area of interest and continued research for, for instance, establishing commercial advantage in the industry.

### SUMMARY

The shortcomings of the prior art are overcome and additional advantages are provided, in one or more aspects, through the provision of a method, which includes: providing an energy storage system including, in part, a capacitor and state of health logic for monitoring the capacitor. The state of health logic facilitates: determining a measured capacitance of the capacitor; estimating an effective series resistance (ESR) of the capacitor; determining, using the measured capacitance and the effective series resistance, a linearized capacitance parameter (CAP) for the capacitor; and signaling should the CAP drop below, or the ESR rise above, a respective specified threshold for the capacitor.

In one or more other aspects, a system is provided which includes a capacitor and state of health logic for monitoring the capacitor during use. The state of health logic facilitates: determining a measured capacitance of the capacitor; estimating an effective series resistance (ESR) of the capacitor; determining, using the measured capacitance and the effective series resistance, a linearized capacitance parameter (CAP) of the capacitor; and signaling should the CAP drop below, or the ESR rise above, a respective specified threshold for the capacitor.

In one or more further aspects, a computer program product is provided for facilitating monitoring capacitance of a capacitor. The computer program product includes a computer-readable storage medium having program instructions embodied therewith, where the computer-readable storage medium is a non-transitory computer-readable storage medium, and the program instructions are executable by a processing circuit to cause the processing circuit to perform a method, which includes: determining a measured capacitance of a capacitor; estimating an effective series resistance (ESR) of the capacitor; determining, using the measured capacitance and the effective series resistance, a linearized capacitance parameter (CAP) of the capacitor, and signaling should the CAP drop below, or the ESR rise above, a respective specified threshold for the capacitor.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 graphically depicts typical aging characteristics of a capacitor;

FIG. 2 graphically depicts, by way of example, the voltage dependent capacitance of both new and old capacitors which is to be monitored, in accordance with one or more aspects of the present invention;

FIG. 3 is a table of a comparison of capacitance to a linearized capacitance parameter in both new and old capacitor devices, in accordance with one or more aspects of the present invention;

FIG. 4A illustrates one embodiment of a method of analyzing a capacitor, in accordance with one or more aspects of the present invention;

FIG. 4B graphically depicts an example embodiment of the method of FIG. 4A, in accordance with one or more aspects of the present invention;

FIG. 5 schematically depicts one embodiment of a system for analyzing a capacitor, in accordance with one or more aspects of the present invention;

FIG. 6 schematically depicts one embodiment of a computer system which facilitates monitoring and/or analyzing a capacitor, in accordance with one or more aspects of the present invention;

FIG. 7 depicts another embodiment of a capacitor of a mobile device which may be monitored and/or analyzed, in accordance with one or more aspects of the present invention; and

FIG. 8 depicts an effective series resistance for a capacitor (shown as a supercapacitor by way of example), in accordance with one or more aspects of the present invention.

### DETAILED DESCRIPTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and not by way of limitation. Various substitutions, modifications, additions, and/or arrangements, within the spirit and/or scope of the underlying inventive concepts will be apparent to those skilled in the art from this disclosure.

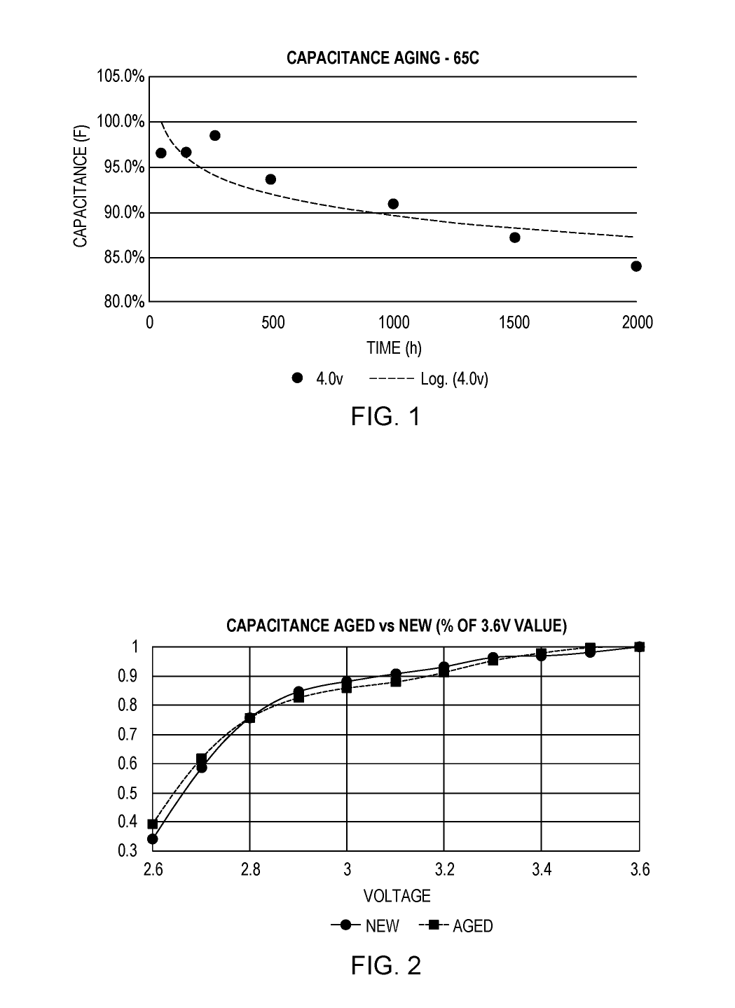

Both traditional and alternative energy storage devices typically degrade as a function of time and use, which can result in a diminishing capacity for energy storage. By way of example, FIG. 1 depicts the capacity of a typical capacitor over a period of time, as measured at 4.0 volts (v).

In view of the observed degradation, it is desirable to assess existing capacity of capacitors used in energy storage and to ensure adequate capability to deliver the required amount of energy at the required power. For example, it may be desirable that the state of health (SOH) of such devices be monitored to determine that their SOH is sufficient for a backup operation, that is, to ensure, for instance, that a capacitor has a minimum threshold of energy remaining, or a minimum amount of operation time remaining. Typically, in backup energy storage applications the energy storage devices cannot be removed from service for a determination of SOH or discharged to an energy level less than that required to perform their backup function. If they were removed or drained, a power disruption during the test could cause a partial or total data loss, defeating the purpose of a persistent energy storage system. Therefore, the SOH determination is highly bolstered if these measurements can be made capacitors which are currently in service, operating, and/or are fully charged. In this way, the primary function of providing adequate energy delivery to the application in the event of power disruption is maintained.

For example, if a user has determined that when a capacitance device, such as an alternate capacitance device, degrades to below a capacitance threshold of 80% of original ‘new’ capacitance, or the ESR rises above a respective threshold, then the device can no longer deliver enough energy for the task at hand. The SOH monitoring may be used to issue an alert to a system control when the value drops to, for instance, 85% of the original value. This alert or signal could then lead to a replacement of the capacitor or other adjustment in the system (e.g., adjust power consumption, decrease temperature, etc.), thus preventing failure of the device or capacitor to perform the task. If the determination was made correctly with an offset of 18% (as the subject of this patent), then the system can be set to read, for instance, the linearized capacitance (CAP), which can then be compared directly to the known rated capacitance of the capacitor.

An SOH determination for traditional devices is facilitated through the measurement of two small signal parameters in the full charge state: capacitance (governed by the equation C=i/(dv/dt) where C is the measured capacitance, i the current entering the device and dv/dt the rate of device voltage change as a function of time) and effective series resistance (governed by the equation ESR=v/I, where ESR is the effective series resistance). With these two parameters, the available energy (from full charge to full discharge or empty) may be determined, given that these parameters remain substantially constant throughout the discharge cycle, as is the case for traditional capacitor devices.

However, in making an SOH determination for an alternative capacitive device (which is shown in FIG. 2), the capacitance is a function of the device voltage. Although alternative capacitive devices are rated in capacitance units (Farads), this parameter is frequently derived though the measurement of energy delivered to a load and then equated back to a linearized capacitance parameter (CAP), given the device voltage v, discharge current i and ESR. For example, in a constant current discharge, the energy delivered to a load from a capacitor equals ½*C*((V_{full}−i*ESR)²−(V_{empty})²), and for alternative capacitive devices, CAP is equated to capacity (C), where V_{full} and V_{empty} are design parameters of the capacitor, as further described below. In alternative capacitive devices, the measured determination of CAP typically requires a full discharge of the device, and thus, the direct measurement of this parameter is not conventionally possible while the device is in service.

Embodiments of determining an SOH described herein can be utilized for both traditional capacitance devices and alternative capacitance devices. However, no other method exists for SOH determination in alternative capacitance devices. Accordingly, most embodiments discussed herein refer to alternative capacitance devices for ease of description, but this is not meant to be limiting.

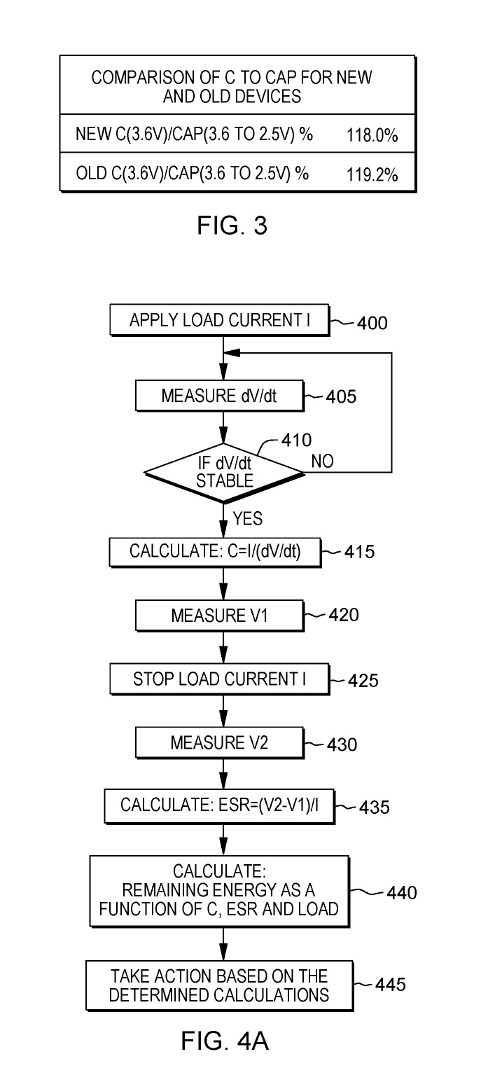

In one or more embodiments, disclosed herein is a method for the determination of the alternative device CAP using a small signal estimation through the measurement of C. With an estimated CAP and the small signal estimate of ESR, the SOH (which can include the remaining energy or the remaining time a capacitor can run) for the alternative capacitive device may be determined, and an action to be taken based on these determinations. Embodiments including this estimation principle are based on several observations. For instance, as illustrated in FIG. 2, as an alternative capacitive device ages, the characteristic profile of capacitance, C, as a function of device voltage is preserved and nearly identical between a new and a used device. For instance, a ‘New’ alternative device may have no degradation in device specifications, but an ‘Old’ or ‘aged’ alternative capacitive device may show signs of degradation in device specifications due to the passage of time, however, the overall profile remains consistent, despite changes in absolute values. Further, the ratio of C/CAP, which can be used for estimating the CAP measurement, for an alternative capacitive device remains essentially constant over the passage of time, as illustrated in FIG. 3. In particular, FIG. 3 shows that the C/CAP ratio varies very little between a new and aged capacitive device. Accordingly, a method according to some embodiments disclosed herein includes estimating the CAP for the device under test given small-signal measurements of C. However, as the small-signal capacitance for an alternative capacitive device is non-linear, C needs to be specified at a particular device voltage, v, which can be denoted by C(v), for instance, as shown in FIG. 1.

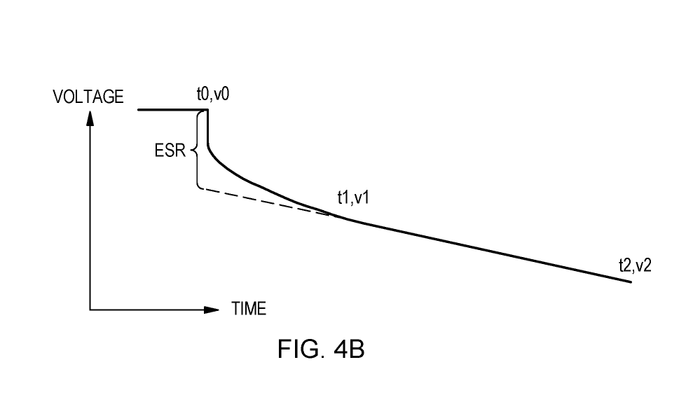

Referring to FIG. 4A, a method according to one or more embodiments is illustrated. For instance, an energy storage system including a capacitor device, as disclosed above, and a state of health logic for monitoring the capacitor may be provided. The state of health logic may be configured to, in one embodiment, analyze the SOH of a capacitor. At 400, a first load current is applied at a known voltage to the capacitor to be analyzed. The measurement of C is then taken utilizing multiple steps. For instance, at 405, a dV/dt, the rate of device (i.e., capacitor) voltage change as a function of time, is measured. If the voltage is not yet stabilized, the process does not continue until a stable measurement is taken. FIG. 4B depicts the voltage profile of a device under measurement as a function of time. Prior to time t0, the open circuit voltage of the device is designated as v0. Immediately following t0 a load current (I) is applied (400; FIG. 4A) resulting in a voltage drop which is representative of the effect of the effective series resistance (ESR). Stabilization occurs in the region after t1 where the slope of the voltage profile is relatively constant. In one embodiment, the criteria for stabilization is when the second derivative of the voltage with respect to time equals zero. An alternative embodiment defines stabilization as the time where the change in measured C divided by the measured C is within a defined threshold of error. Upon acquiring stability, C, the capacitance is measured at 415, which may be estimated, utilizing numerical methods, by the equation C=I/(dV/dt). The current leaving the device (known variable I) is divided by the dv/dt as measured, resulting in the measured capacitance C. In one embodiment, ESR may be estimated by the instantaneous drop in device voltage on application of current (i) given by the equation ESR=V/I. In an alternate embodiment ESR is estimated by the difference in the open circuit voltage (v0) minus the voltage projected back to t0 from the point of stability using dv/dt projection divided by the current i. For instance, at 420, the first voltage is measured, at 425 the first current load is stopped, and at 430, the second voltage is measured to determine a voltage drop. At 435, the voltage drop is used to calculate the ESR. Referring to the depiction of FIG. 4B, a simplified numerical method, ESR=(vo−(v1+(t0−t1)dV/dt)/I may be used. Another embodiment would measure a first voltage under load current I, stop the load current and measure a second voltage whereby the effective series resistance (ESR) is calculated by the change in voltage divide the load current (ESR=v/i). Then at 440, the remaining energy may be determined as a function of the measured C, the estimated ESR, and the known load applied. At 445 an action may be taken, for instance, by the state of health logic. In some embodiments, the action may include lowering the power drawn from the capacitor, lowering the operating temperature of the capacitor, or signaling for a replacement capacitor. Since the rate of degradation of the capacitance is linear and predictable, the replacement signal can include an indication of the hours, days, weeks, or even months before replacement is necessary. The signaling can be on a display connected to a computer system including the capacitor, for instance.

For instance, the remaining energy, or SOH of the capacitance can be acquired by converting the measured capacitance to the CAP, by multiplying the measured C by the conversion factor, an example of which is given in FIG. 3. This will give a CAP value which may be used to estimate the energy remaining (SOH), which is determined using estimated CAP and ESR by formula or iterative means, as depicted in FIGS. 3, 4A and 4B.

While the measurement of C is described above in terms of V_{full} and the empty voltage (V_{empty}), it should be understood that V_{full} and V_{empty} are set voltages which typically include design parameters set by the manufacturer of a capacitor. Their values are constrained to ensure the long term reliability of the alternative capacitive device, and thus may be set by the factory. While some embodiments are described as using these values, alternate embodiments may include raising or lowering the device voltage to facilitate testing of SOH using various estimation parameters without loss of generality. For instance, certain devices may give more accurate results at different voltages than the V_{full} and V_{empty}. Additionally, the overall capacity described above is a measurement of the linearized capacitance when measured by discharge (or conversely charge in further embodiments) from one voltage, e.g., V_{full}, to a second voltage, e.g., V_{empty}, and is denoted by CAP(V_{full} to V_{empty}). That is, CAP is the desired parameter for SOH estimation and is not directly observable for an in-service alternative capacitance device. Given a measured C(V_{full}), CAP(V_{full} to V_{empty}) may be estimated by the conversion ratio as shown in FIG. 3, which may be C(V_{full})/CAP(V_{full} to V_{empty}) for a new alternative capacitive device (C_to_CAP), however other values besides V_{full} and V_{empty} can be used in this determination.

Once the SOH has been determined, which can include the remaining power of the capacitor, or the remaining time that a capacitor may run, a determination may be made whether the capacitor is healthy enough and has enough power to convert temporary data storage to a permanent data storage should an interruption in power or a power failure occur. This determination may include converting the SOH result to a percentage power or time of power, and can be used to determine if the capacitor is capable of operating in the desired way.

For example, in one or more embodiments, once an SOH of, for instance, a hybrid supercapacitor, is measured, the voltage or temperature may be dynamically adjusted in the system so that the aging of the device CAP and ESR can be slowed down. As a further example, in one or more alternate embodiments, one or more additional supercapacitors may be added to supplement the needed power or replace the existing device. In another further example, the SOH subsequent readings may be used to monitor the rate of degradation, and if the rate of degradation of any one supercapacitor is higher than the ‘average rate’ or norm expected, then an alert could be sent, and the above actions may be taken.

In a further embodiment, certain measurement and control features can be used for a system 500 for analyzing SOH for a capacitor. For instance, system 500 may include an SOH measurement and control device for taking the measurements described herein, as well as a time monitoring device to facilitate determining capacitance (C) and resistance (ESR). Still further, a known discharge load device 502 may be provided for applying a load to the capacitor 503.

FIG. 6 depicts a block diagram of one example of a computing environment to incorporate, implement or use one or more aspects of the present invention. A set of components referred to herein as a computing environment 600 may include a data processing system 601. System 601 may include a processor (in this example a central processing unit (CPU)) 602 for performing computations. CPU 602 may be coupled to a bus bridge 606 by way of a CPU bus 604. Bus bridge 606 may include a memory controller (not shown) integrated therein, though the memory controller may be external to bus bridge 606. The memory controller may provide an interface for access by CPU 602 or other devices to system memory 608. System memory 608 can include any of a variety of types of memory device or memory circuitry for storing data. Bus bridge 606 may optionally be coupled to graphics circuitry 610 for controlling an optional display device 612. Graphics circuitry 610 may include, in one example, a video controller, video memory for storing display data to be displayed on display device 612, and a video BIOS that includes code and video services for controlling the video controller, as is well known in the art. In another embodiment, graphics circuitry 610 may be coupled to CPU 602 through an Advanced Graphics Port (AGP) bus.

Bus bridge 606 may also be coupled to a system bus 614 that may be a peripheral component interconnect (PCI) bus, Industry Standard Architecture (ISA) bus, etc., and combinations thereof, as examples. Coupled to system bus 814 may optionally be a communication device 616, mouse 618, keyboard 620, non-volatile memory 622, and mass storage 624. One or more other input/output (I/O) devices (not shown) may also be coupled to system bus 614.

Mass storage device 624, if provided, can be any of numerous different types of such devices including a hard disk, floppy disk, CD-ROM, DVD-ROM, tape, high density floppy, high capacity removable media, low capacity removable media, solid state memory device, etc., and combinations thereof. Non-volatile memory 622 may be a read-only memory (ROM), flash memory, etc., and can include a system BIOS for controlling, among other things, hardware devices in data processing system 601. The capacitor 503 may be a part of non-volatile memory 622 for transferring data to mass storage device 624 in the case of power loss or interruption.

As is familiar to those having ordinary skill in the art, system 601 further includes an operating system 626, which is loaded into system memory 608 from mass storage device 624, for instance, and launched after a power-on self-test (POST). Operating system 626 includes a set of one or more programs that control computer system 601's operation and the allocation of resources thereof, among other things. Example operating systems include, but are not limited or restricted to, DOS, Unix, Linux, the Windows® line of operating systems offered by Microsoft Corporation, Redmond, Wash., and the “OS” line of operating systems (such as OS X®) offered by Apple Inc., Cupertino, Calif., etc. Also loaded into memory 608 of the computer system 601 is a control program 628 hosted by a hosting application 629. Control program 628 may be, in one or more embodiments, program code, which implements one or more aspects of the processing described herein. For instance, program code for carrying out the method described above using SOH device 500, which may be connected to bridge 806 may be contained within control program 828, including determining that the capacitor fell below a threshold energy, or the ESR rises above a respective threshold, and taking action such as lowering the power down from the capacitor and/or the temperature at which the capacitor is running, or signaling that the capacitor requires replacement, in some instances, indicating a timeframe by which to replace the capacitor.

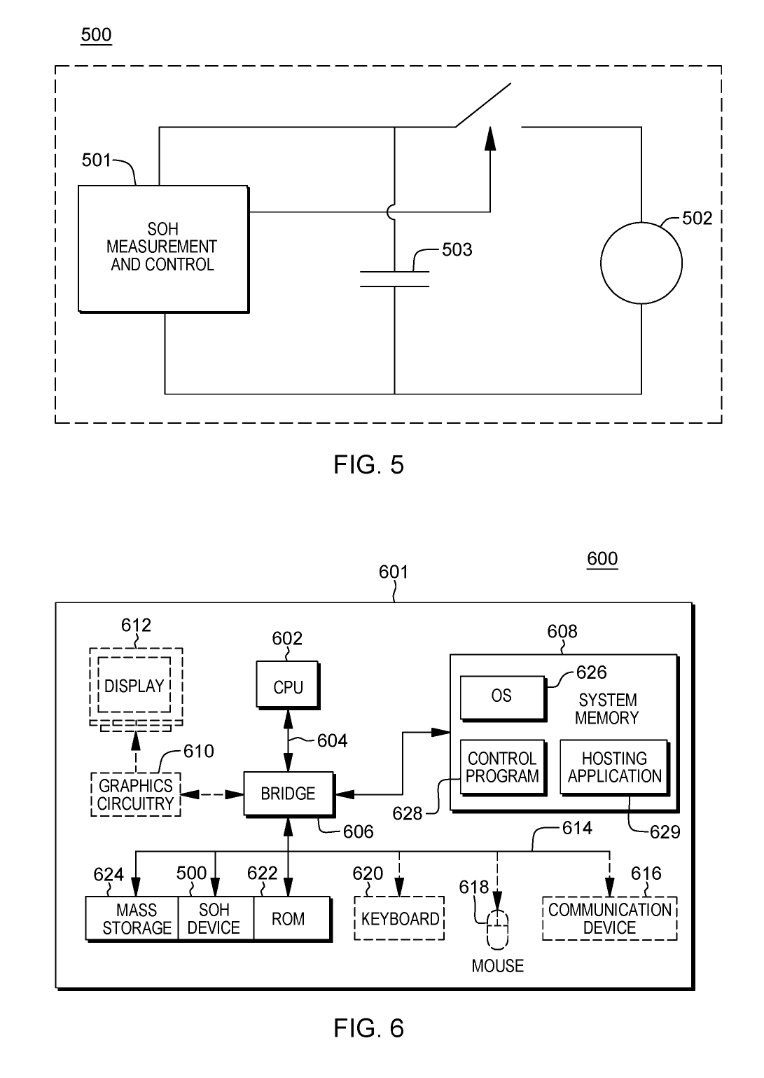

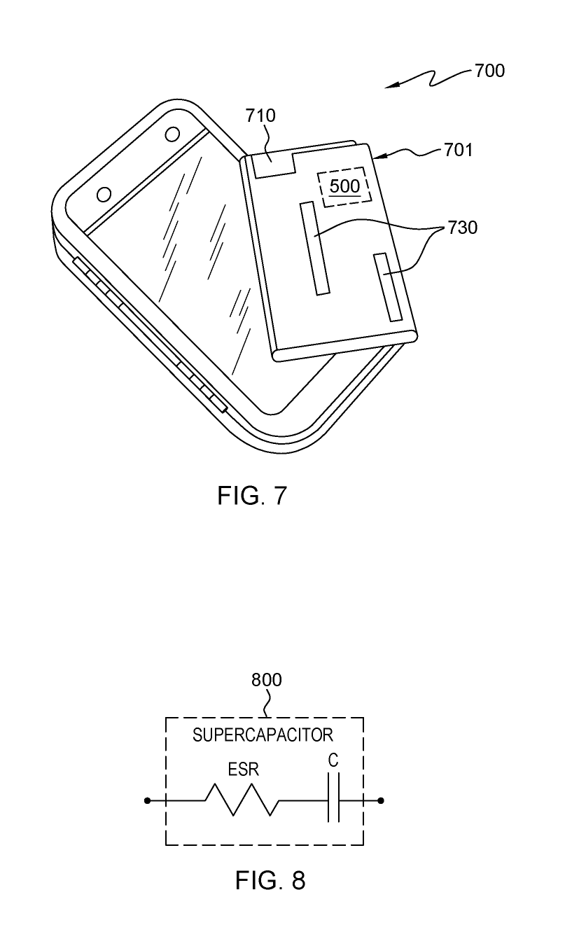

FIG. 7 illustrates a mobile phone type electronic system 700, in accordance with one or more aspects of the present invention. As illustrated, electronic system 700 may include an ultra-capacitor structure 701, rather than (for instance) a capacitor 503 such as shown in FIG. 5. As depicted in FIG. 7, the ultra-capacitor structure 701 may include at least one ultra-capacitor cell 710 and a battery, the battery being capable of charging the at least one ultra-capacitor structure. In such a case, an ultra-capacitor structure may be integrated with one or more battery cells, and may be used to provide a removable source of power for the electronic system. In one example, the battery may be completely wrapped by the ultra-capacitor structure, to allow for electromagnetic shielding thereof. An SOH device 500, similar to that shown in FIG. 5, may be included with mobile electronic system 700 to monitor the SOH of the ultra-capacitor, using the processes described above.

By way of further example, FIG. 8 depicts an ideal model of a supercapacitor 800, which includes an ideal capacitor (C) in series with an ideal resistor (ESR). In one or more other embodiments, a simplified model of a dual layer structure 701 (FIG. 7) may include a terminal resistance (ESR) in series with an ideal capacitance (C) in series with an internal resistance (ESR) in series with an ideal capacitance (C) in series with another terminal resistance (ESR). This particular model depicted is representative of the structure found in EDLC and asymmetric supercapacitor devices. With either model, the supercapacitor is limited in voltage operation due to electrolyte breakdown and active material decomposition. Both these factors lead to capacitor degradation if the capacitor (C) plate potential is not constrained to a prescribed voltage limit. As opposed to batteries, which are electrical current limited, supercapacitors are typically power limited in their exchange of energy, which advantageously allows greater degrees of freedom in the charging approach.

The present invention may be a system, a method, and/or a computer program product, any of which may be configured to perform or facilitate aspects described herein.

In some embodiments, aspects of the present invention may take the form of a computer program product, which may be embodied as computer readable medium(s). A computer readable medium may be a tangible storage device/medium having computer readable program code/instructions stored thereon. Example computer readable medium(s) include, but are not limited to, electronic, magnetic, optical, or semiconductor storage devices or systems, or any combination of the foregoing. Example embodiments of a computer readable medium include a hard drive or other mass-storage device, such as mass storage device 624 (FIG. 6), an electrical connection having wires, random access memory (RAM), read-only memory (ROM), such as non-volatile memory 622 (FIG. 6), erasable-programmable read-only memory such as EPROM or flash memory, an optical fiber, a portable computer disk/diskette, such as a compact disc read-only memory (CD-ROM) or Digital Versatile Disc (DVD), an optical storage device, a magnetic storage device, or any combination of the foregoing. The computer readable medium may be readable by a processor, processing unit, or the like, to obtain data (e.g. instructions) from the medium for execution. In a particular example, a computer program product is or includes one or more computer readable media that includes/stores computer readable program code to provide and facilitate one or more aspects described herein.

As noted, program instructions contained or stored in/on a computer readable medium can be obtained and executed by any of various suitable components such as a processor of a computer system to cause the computer system to behave and function in a particular manner. Such program instructions for carrying out operations to perform, achieve, or facilitate aspects described herein may be written in, or compiled from code written in, any desired programming language. In some embodiments, such programming language includes object-oriented and/or procedural programming languages such as C, C++, C#, Java, etc.

Program code can include one or more program instructions obtained for execution by one or more processors. Computer program instructions may be provided to one or more processors of, e.g., one or more computer systems, to produce a machine, such that the program instructions, when executed by the one or more processors, perform, achieve, or facilitate aspects of the present invention, such as actions or functions described in flowcharts and/or block diagrams described herein. Thus, each block, or combinations of blocks, of the flowchart illustrations and/or block diagrams depicted and described herein can be implemented, in some embodiments, by computer program instructions.

Though the descriptions contained in this disclosure specifically reference data storage as the application for the present invention, it is asserted that any application requiring the knowledge of the present time energy delivery capability of a non-linear capacitive storage device would benefit from the method taught herein. These may include, but not limited to: UPS function, emergency lighting and jump start devices.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components and/or groups thereof.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description, but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A method comprising:
providing an energy storage system comprising, in part, a capacitor and state of health logic for monitoring the capacitor, the state of health logic:
determining a measured capacitance of the capacitor;
estimating an effective series resistance (ESR) of the capacitor;
determining, using the measured capacitance and the effective series resistance, a linearized capacitance parameter (CAP) for the capacitor; and
signaling should the CAP drop below, or the ESR rise above, a respective specified threshold for the capacitor.

2. The method of claim 1, further comprising determining, using the CAP and the effective series resistance, an amount of energy remaining in the capacitor.

3. The method of claim 2, wherein the energy remaining is in terms of remaining time the capacitor can function.

4. The method of claim 1, wherein the capacitor comprises a supercapacitor.

5. The method of claim 1, wherein the capacitance is measured at a particular voltage.

6. The method of claim 5, wherein voltage comprises a device full value.

7. The method of claim 1, wherein the CAP is estimated using the equation: C(V_{full})/CAP(V_{full} to V_{empty}), where C is the measured capacitance, and V_{full} and V_{empty} are known voltages for the capacitor.

8. A system comprising:
a capacitor; and
state of health logic for monitoring the capacitor during use, the state of health logic:
determining a measured capacitance of the capacitor;
estimating an effective series resistance (ESR) of the capacitor;
determining, using the measured capacitance and the effective series resistance, a linearized capacitance parameter (CAP) of the capacitor; and
signaling should the CAP drop below, or the ESR rise above, a respective specified threshold for the capacitor.

9. The system of claim 1, further comprising the state of health logic:
determining, using the CAP and the effective series resistance, an amount of energy remaining in the capacitor.

10. The system of claim 2, wherein the energy remaining is in terms of remaining time the capacitor can function.

11. The system of claim 1, wherein the capacitor comprises a supercapacitor.

12. The system of claim 1, wherein the capacitance is measured at a particular voltage.

13. The system of claim 5, wherein voltage comprises a device full value.

14. The system of claim 1, wherein the CAP is estimated using the equation: C(V_{full})/CAP(V_{full} to V_{empty}), where C is the measured capacitance, and V_{full} and V_{empty} are known voltages for the capacitor.

15. A computer program product for monitoring a capacitor, the computer program product comprising:
a computer-readable storage medium having program instructions embodied therewith, the computer-readable storage medium being a non-transitory computer-readable storage medium, and execution of the program instructions by a processing circuit cause the processing circuit to perform a method comprising:
determining a measured capacitance of a capacitor;
estimating an effective series resistance (ESR) of the capacitor;
determining, using the measured capacitance and the effective series resistance, a linearized capacitance parameter (CAP) of the capacitor;
determining, using the CAP and the effective series resistance, an amount of energy remaining in the capacitor; and
signaling should the CAP drop below, or the ESR rise above, a respective specified threshold for the capacitor.

16. The computer program product of claim 15, wherein the energy remaining is in terms of remaining time the capacitor can function.

17. The computer program product of claim 15, wherein the capacitor comprises a supercapacitor.

18. The computer program product of claim 17, wherein the capacitance is measured at a particular voltage.

19. The computer program product of claim 17, wherein voltage comprises a device full value.

20. The computer program product of claim 15, wherein the CAP is estimated using the equation: C(V_{full})/CAP(V_{full} to V_{empty}), where C is the measured capacitance, and V_{full} and V_{empty} are known voltages for the capacitor.
